(19) United States
(12) Patent Application Publication
(10) Pub. No.: US 2020/0411794 A1
(43) Pub. Date: Dec. 31, 2020

(54) ORGANIC LIGHT EMITTING DIODE DISPLAY DEVICE AND METHOD OF FABRICATING SAME

(71) Applicant: WUHAN CHINA STAR OPTOELECTRONICS SEMICONDUCTOR DISPLAY TECHNOLOGY CO., LTD., WUHAN, HUBEI (CN)

(72) Inventors: Jing HUANG, WUHAN, HUBEI (CN); HSIANGLUN HSU, WUHAN, HUBEI (CN)

(21) Appl. No.: 16/615,394

(22) PCT Filed: Aug. 22, 2019
(86) PCT No.: PCT/CN2019/102016

§ 371 Date: Nov. 20, 2019

(30) Foreign Application Priority Data
Apr. 30, 2019 (CN) 201910361105.2

(51) Int. Cl. H01L 51/52; H01L 51/56

(52) U.S. Cl. CPC H01L 51/5253; H01L 2251/301; H01L 51/56

(57) ABSTRACT

The present invention provides an organic light emitting diode display device and a method of fabricating the same. The organic light emitting diode display device includes an array substrate, a light emitting layer, and an encapsulation layer which are stacked, wherein the encapsulation layer includes a first inorganic layer, a first metal layer, an organic layer, a second metal layer, and a second inorganic layer. The method of fabricating the organic light emitting diode display device, comprising the following steps: forming an organic light emitting diode; forming a first inorganic layer; forming a first metal layer; forming an organic layer; forming a second metal layer; and forming second inorganic layer. The present invention can effectively improve the bonding strength between the organic layer and the inorganic layer, and ensure good water and oxygen barrier performance and bending resistance.

### BACKGROUND OF INVENTION

### Field of Invention

The present invention relates to a field of display, and in particular, to an organic light emitting diode display device and a method of fabricating the same.

### Description of Prior Art

An organic light emitting diode (OLED) display device has many advantages such as low driving voltage, high luminous efficiency, flexibility facilitation, and compatibility facilitation, and is recognized as one of the most promising display technologies in the industry. However, since the device widely use water/oxygen-sensitive organic materials, in order to prevent it from being eroded by water and oxygen, effective packaging means is required. At present, a relatively mature packaging method of an organic light emitting diode display device is to use a metal or glass cover for packaging, but it cannot meet development needs of flexible display. Thin film packaging is considered to be the key to breakthroughs in flexible displays. An inorganic metal oxide film has good moisture and oxygen barrier properties, but has poor bending resistance; while an organic film has good ductility, but has poor barrier property. In comparison, some pure metal films (aluminum as a representative) have good mechanical properties and water-oxygen barrier properties, and are expected to be applied to packaging of flexible electronic devices.

For preparation of pure metal film, existing physical vapor deposition (evaporation, magnetron sputtering) methods are difficult to accurately control a film thickness, and film defect sites (pinholes, etc.) are highly dense, which is not suitable for packaging of flexible display device. Although the metal film has good water-oxygen barrier properties, when it is directly plated on the surface of the device, it tends to cause a short circuit in loading voltage of the device. Moreover, although the single inorganic metal oxide film has a certain barrier property, its bending resistance is poor, and it is more likely to cause cracks due to stress concentration, resulting in failure due to rapid erosion by water and oxygen. Therefore, each of the inorganic layer and metal layer has its own shortcomings.

In addition, an existing encapsulation layer structure generally adopts a form of alternating inorganic-organic-inorganic multilayered structure. The emerging atomic layer deposition technology (ALD) can be used to prepare a nano-scaled inorganic metal oxide film as an inorganic layer, and the prepared film has good conformity and high step coverage, and has been widely used in a field of large-scaled semiconductor fabricating. Although the inorganic metal oxide film has a certain barrier property, its bending resistance is poor, and it is more likely to cause cracks due to stress concentration, resulting in failure due to rapid erosion by water and oxygen. Moreover, bonding strength between the inorganic layer and the organic layer is poor, resulting a poor structural stability of the encapsulation layer.

### SUMMARY OF INVENTION

An object of the present invention is to overcome the defects of the prior art, and accordingly an organic light emitting diode display device and a method of fabricating the same are provided, which can solve the problem that in the prior art, the inorganic metal oxide film has poor bending resistance and is more likely to cause cracks due to stress concentration, resulting in failure due to rapid erosion by water and oxygen. Moreover, the technical problem that the bonding strength between the inorganic layer and the organic layer is poor, resulting a poor structural stability of the encapsulation layer can be solved.

In order to solve the above problems, the present invention provides an organic light emitting diode display device including an array substrate, a light emitting layer, and an encapsulation layer which are stacked, wherein the encapsulation layer includes a first inorganic layer, a first metal layer, an organic layer, a second metal layer, and a second inorganic layer. Specifically, the light emitting layer is disposed on a side of the light emitting layer facing away from the array substrate; the first metal layer is located on the first inorganic layer; the organic layer is located on the first metal layer; the second metal layer is located on the organic layer; and the second inorganic layer is located on the second metal layer.

Further, the first inorganic layer and the second inorganic layer are prepared by atomic layer deposition

Further, the first metal layer and the second metal layer are made of a material including aluminum.

Further, each of the first metal layer and the second metal layer has a thickness ranging from 50 to 150 nm.

Further, the organic layer includes doped particles, and the doped particles include desiccant particles and a coupling agent.

The present invention also provides a method of fabricating an organic light emitting diode display device, including the following steps:

forming an organic light emitting diode, by forming a light emitting layer on an array substrate, such that the array substrate and the light emitting layer form the organic light emitting diode;

forming a first inorganic layer, by depositing the first inorganic layer by atomic layer deposition on a surface of a side of the light emitting layer of the organic light emitting diode facing away from the array substrate;

forming a first metal layer, by preparing the first metal layer on the first inorganic layer;

forming an organic layer, by preparing the organic layer on a surface of a side of the first metal layer facing away from the first inorganic layer;

forming a second metal layer, by preparing the second metal layer on the organic layer;

forming second inorganic layer, by depositing the second inorganic layer on the second metal layer by atomic layer deposition, wherein the second inorganic layer completely covers the second metal layer.

Further, before the step of forming the first metal layer, the method further includes: after completing the depositing of the first inorganic layer on the organic light emitting diode display device, plasma treating a surface of the first inorganic layer.

Further, before the step of forming the second inorganic layer, the method further includes: after completing the depositing of the second metal layer on the organic light emitting diode display device, plasma treating the surface of the side of the second metal layer facing away from the organic layer.

Further, the first metal layer and the second metal layer are prepared by atomic deposition, and each of the first metal layer and the second metal layer has a thickness ranging from 50 to 150 nm.

The present invention has an advantageous effect of providing an organic light emitting diode display device and a method of fabricating the same, which makes the entire encapsulation layer thinner by providing a metal layer between the inorganic layer and the organic layer of the encapsulation layer, thereby enhancing the bonding strength between the organic layer and the inorganic layer, avoiding the defects of the inorganic layer and the metal layer when used alone, improving the stability thereof, ensuring good water-oxygen barrier property and bending resistance, and satisfying requirements of the flexible electronic packaging technology.

### BRIEF DESCRIPTION OF DRAWINGS

FIG. 1 is a schematic structural view of an organic light emitting diode display device according to an embodiment of the present invention.

FIG. 2 is a flow chart showing fabrication of an organic light emitting diode display device according to an embodiment of the present invention.

FIG. 3 is a schematic view showing the structure of steps S1-S3 in FIG. 2.

FIG. 4 is a schematic view showing the structure after completing the step of forming the second metal layer in FIG. 2.

FIG. 5 is a comparison diagram of hydrophilic effects after the ultraviolet irradiation curing treatment of the organic layer in the step of forming the organic layer in FIG. 2 is completed.

FIG. 6 is a graph showing the dielectric properties of the first inorganic layer.

Elements in the drawings are designated by reference numerals listed below. 10 array substrate, 20 light emitting layer, 30 encapsulation layer, 31 first inorganic layer, 32 first metal layer, 33 organic layer, 34 second metal layer, 35 second inorganic layer, 36 organic film mask frame, 100 organic light emitting diode display device, 331 doped particle.

### DETAILED DESCRIPTION OF PREFERRED EMBODIMENTS

In the present invention, unless otherwise expressly stated and limited, the formation of a first feature over or under a second feature in the description that follows may include embodiments in which the first and second features are formed in direct contact, and may also include embodiments in which additional features may be formed between the first and second features, such that the first and second features may not be in direct contact. Moreover, the first feature “above”, “over” and “on” the second feature includes the first feature directly above and above the second feature, or merely indicating that the first feature is at a level higher than the second feature. The first feature “below”, “under” and “beneath” the second feature includes the first feature directly below and obliquely below the second feature, or merely the first feature has a level lower than the second feature.

In the present invention, the same or corresponding components are denoted by the same reference numerals regardless of the figure numbers, and throughout the specification, when the terms “first”, “second” and the like can be used to describe various components, these components are not necessarily limited to the above terms. The above terms are only used to distinguish one component from another.

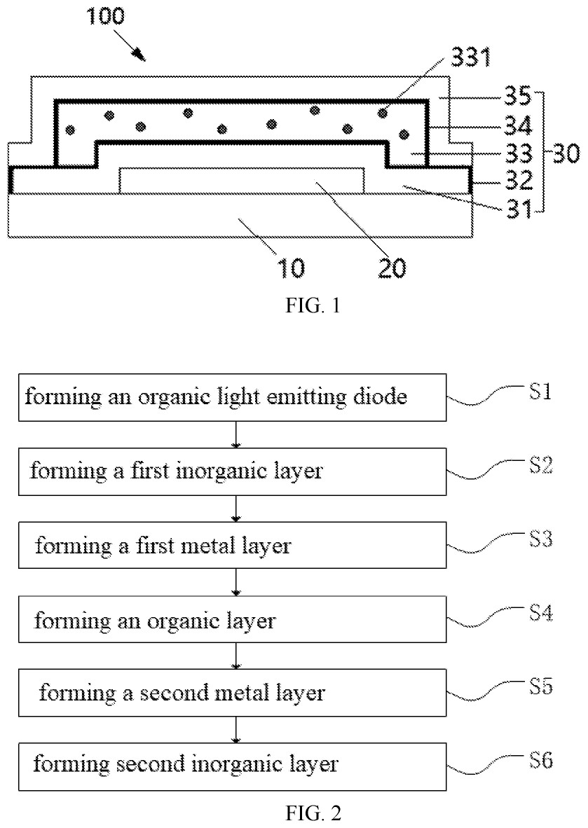

Referring to FIG. 1, an embodiment of the present invention provides an organic light emitting diode display device 100 including an array substrate 10, a light emitting layer 20, and an encapsulation layer 30 which are stacked. In particular, the light emitting layer 20 is located in the on the array substrate 10, the encapsulation layer 30 is located on a side of the light emitting layer 20 facing away from the array substrate 10, wherein the encapsulation layer 30 includes a first inorganic layer 31, a first metal layer 32, an organic layer 33, a second metal layer 34, and a second inorganic layer 35. Specifically, the first metal layer 32 is located on the first inorganic layer 31, the organic layer 33 is located on the first metal layer 32, the second metal layer 34 is located at the on the organic layer 33, and the second inorganic layer 35 is located on the second metal layer 34.

In the present embodiment, the first inorganic layer 31 and the second inorganic layer 35 include an inorganic metal oxide film or an inorganic metal nitride film. Specifically, the first inorganic layer 31 and the second inorganic layer 35 include Al₂O₃, ZrO, HfO, or SiN_{X}. Preferably, the first inorganic layer 31 and the second inorganic layer 35 are Al₂O₃. Plasma cleaning a surface of the Al₂O₃ (aluminum oxide film) can improve free energy and hydrophilicity of the surface, thereby facilitating uniform deposition on the surfaces of the first metal layer 32 and the second metal layer 34. In addition, the Al₂O₃ (aluminum oxide film) has better water-oxygen barrier properties due to its own compactness, which can protect the surface of the device from being damaged by secondary electrons, ions, and the like. Further, the Al₂O₃ (aluminum oxide film) prevents the first metal layer 32 from direct contact with the organic light emitting diode display device 100 to form a short circuit.

In this embodiment, each of the first inorganic layer 31 and the second inorganic layer 35 has a dielectric constant of 5 to 11, preferably 7. Each of the first inorganic layer 31 and the second inorganic layer 35 has a thickness ranging from 0.02 to 0.05 um in order to realize lightness and thinning of the encapsulation layer and good water and oxygen barrier properties. The first inorganic layer 31 and the second inorganic layer 35 are all prepared by atomic layer deposition, and the atomic layer deposition technology can be used for preparing a nano-scaled inorganic metal oxide film, and the prepared film has good conformity, and high step coverage, and thus can be widely used in a field of large-scaled semiconductor fabrication.

In this embodiment, the materials of the first metal layer 32 and the second metal layer 34 are preferably aluminum, because the aluminum film itself has good water and oxygen barrier ability, which can form a dense aluminum oxide layer by auto-oxidation to prevents the inner layer from continuing to be eroded. Of course, the materials of the first metal layer 32 and the second metal layer 34 may also be other metals, such as copper, which are all within the scope of the present invention. In this embodiment, the first inorganic layer 31 is an aluminum oxide film, and the first metal layer 32 is an aluminum film. The aluminum film itself has good flexibility and ductility, and the aluminum film (e.g. the first metal layer 32 and the second metal layer 34) can effectively decouple the defect sites of the inorganic film (e.g. the first inorganic layer 31 or the second inorganic layer 35). A combination of the aluminum film and the inorganic film ensures a stable and effective barrier. In addition, the first metal layer 32 is located between the first inorganic layer 31 and the organic layer 33, and the second metal layer 34 is located between the organic layer 33 and the second inorganic layer 35, to improve weak bonding strength between some organic films and inorganic films due to different properties between the organic films and the inorganic films and different bonding ways between their interfaces. The weak bonding strength may lead to delamination from the interfaces under action of external force, thereby losing protection effect on the device. In addition, the film structure of the interface between the organic film and the inorganic film may also be changed due to the mutual influence, resulting in problems such as poor uniformity of the deposited film and poor light transmittance. By providing the first metal layer 32 between the first inorganic layer 31 and the organic layer 33, and by providing the second metal layer 34 between the organic layer 33 and the second inorganic layer 35, the bonding strength between the laminated barrier layers can be improved, and can solve the above problems, thereby realizing reliable packaging of the organic light emitting diode display device 100.

The first metal layer 32 and the second metal layer 34 are prepared by magnetron sputtering. Each of the first metal layer 32 and the second metal layer 34 has a thickness ranging from 50 to 150 nm, preferably 100 nm.

In the present embodiment, the organic layer 33 includes doped particles 331 therein. The doped particles 331 include desiccant particles and a coupling agent. The desiccant particles include, but are not limited to, calcium chloride, phosphorus pentoxide, magnesium perchlorate, anhydrous potassium carbonate or anhydrous calcium sulfate. The desiccant particles can be used to absorb moisture, to enhance hydrophilicity and a water oxygen barrier property of the organic layer 33. If an outer layer of the organic layer 33 is eroded, moisture which enters the organic layer 33 by erosion is absorbed by the desiccant particles, thereby preventing an inner layer from being continuously eroded. The coupling agent includes a zirconium-based coupling agent. The organic layer 33 is made of an organic material including an epoxy resin, a polydimethylsiloxane (PDMS), or a photoresist.

Referring to FIG. 2, an embodiment of the present invention provides a method of fabricating an organic light emitting diode display device 100, including steps S1-S6.

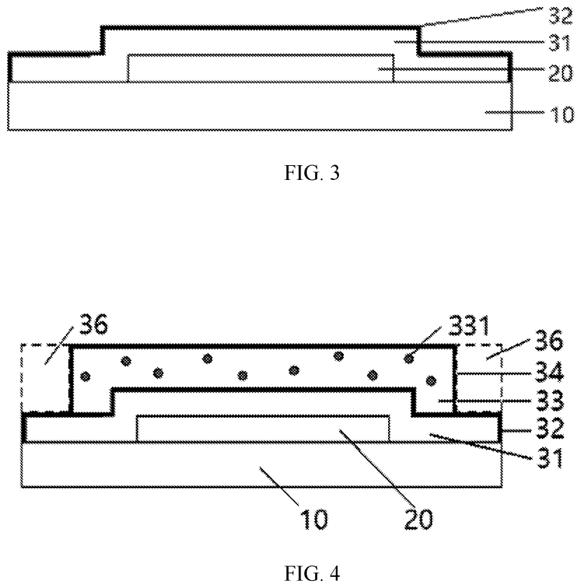

As shown in FIG. 2 and FIG. 3, the step S1 is to form an organic light emitting diode, by forming a light emitting layer 20 on an array substrate 10, such that the array substrate 10 and the light emitting layer 20 form the organic light emitting diode.

Referring to FIG. 2 and FIG. 3, the step S2 is to form a first inorganic layer, by depositing a first inorganic layer 31 by atomic layer deposition on a surface of a side of the light emitting layer 20 of the organic light emitting diode facing away from the array substrate 10 Specifically, the first inorganic layer 31 having a dielectric constant of 5 to 11 is prepared on the light emitting layer 20 of the organic light emitting diode by atomic layer deposition, and the first inorganic layer 31 includes an inorganic metal oxide film or an inorganic metal nitride film, specifically including Al₂O₃, ZrO, HfO, or SiN_{X}. The first inorganic layer 31 has a thickness ranging from 0.02 to 0.05 um.

Referring to FIG. 2 and FIG. 3, the step S3 is to form a first metal layer, by preparing the first metal layer 32 on the first inorganic layer 31. In this embodiment, the first inorganic layer 31 is first placed in a vacuum reaction chamber of an atomic layer deposition apparatus, treated with plasma to increase its surface activity; and the first metal layer 32 having a thickness ranging from 50 to 150 nm is formed on the first inorganic layer 31 by magnetron sputtering. The first metal layer 32 is made of a material including aluminum.

As shown in FIG. 3, a schematic diagram of the semi-finished structure after completing the steps S1-S3 is shown.

Before the step S3 of forming the first metal layer, the method further includes: after completing the depositing of the first inorganic layer 31 on the organic light emitting diode display device, plasma treating a surface of the first metal layer 32.

Plasma cleaning the surface of the first inorganic layer 31 (aluminum oxide film) can improve the hydrophilicity of the surface, and improve the adsorption property of the first metal layer 32 (metal aluminum film), resulting in the more uniform film formed. The longer of the plasma cleaning of the first inorganic layer 31, the better the hydrophilicity of the surface of the film.

A nano-scaled first metal layer 32 (metal aluminum film) is prepared on the surface of the first inorganic layer 31 (aluminum oxide film) by magnetron sputtering. The specific process is performed at a sputtering power of 2000-3000 W with a sputtering pressure of 0.5 Pa, the distance between the target and the substrate is 80 mm, Ar gas flow is 170 sccm, and the surface of the substrate has a temperature of 90° C. Since the first inorganic layer 31 (aluminum oxide film) has been deposited on the surface, it can protect the surface of the device from being damaged by secondary electrons, ions, or the like. Further, the first inorganic layer 31 (aluminum oxide film) prevents the first metal layer 32 (metal aluminum film) from direct contact with the device to form a short circuit.

Referring to FIG. 2 and FIG. 4, the step S4 is to form an organic layer, by preparing the organic layer 33 on a surface of a side of the first metal layer 32 facing away from the first inorganic layer 31. Specifically, an organic solution of a certain concentration is prepared, and the doped particles 331 are doped in the organic solution by a certain proportion, wherein organic substances in the organic solution include but are not limited to epoxy resin, polydimethylsiloxane, or a photoresist; the doped particles 331 include desiccant particles and a coupling agent; the desiccant includes, but not limited to, calcium chloride, phosphorus pentoxide, magnesium perchlorate, anhydrous potassium carbonate, or anhydrous calcium sulfate; and the coupling agent includes, but is not limited to, a zirconium coupling agent. The organic solution is uniformly mixed and then degassed in a vacuum chamber. A layer of electrostatic adsorption organic film mask frame 36 is coated to cover both ends of the first metal layer 32, and the prepared organic solution is dropped on a surface of the first metal layer 32 by spin coating to form an organic layer 33 having a thickness of 1-2 um on the surface of the first metal layer 32. After the organic layer 33 is uniformly applied and solvent is evaporated, the organic film mask frame 36 is removed, followed by heat-curing, and the cured organic layer 33 is subjected to ozone/ultraviolet radiation for 20 h by using an ozone ultraviolet lamp for curing.

FIG. 4 is a schematic diagram showing the semi-finished structure after completing the step S4.

The hydrophilicity and the water oxygen barrier property of the organic layer 33 are enhanced by doping the doped particles 331 in the organic layer 33 and ultraviolet irradiating the organic film 33.

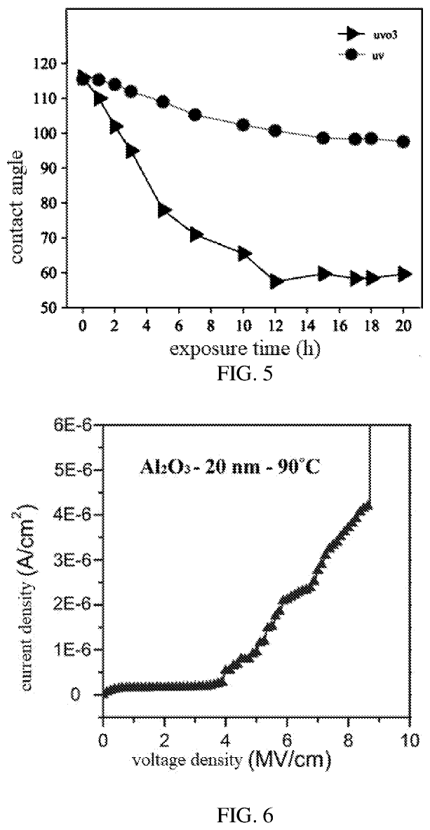

FIG. 5 is a comparison diagram showing hydrophilic effects after completing the ultraviolet irradiation curing treatment of the organic layer in the step S4. After the heat-cured polydimethylsiloxane organic film was irradiated by the ozone ultraviolet lamp for 20 h, a static contact angle of the surface of the film was significantly reduced, and hydrophilicity was significantly improved, compared with the film untreated with the ozone ultraviolet lamp.

Referring to FIG. 2 and FIG. 4, step S5 is to form a second metal layer, and a second metal layer 34 is formed on the organic layer 33. In the present embodiment, a second metal layer 34 of 50-150 nm is prepared on the organic layer 33 by magnetron sputtering; the material of the second metal layer 34 includes aluminum. In this embodiment, the second metal layer 34 is fabricated in the same manner as the first metal layer 32, and is prepared by an atomic deposition method, and the materials of the two are also the same. The first metal layer and the second metal layer each have a thickness of 50 to 150 nm. Of course, in other embodiments, the materials of the second metal layer 34 and the first metal layer 32 may be changed according to actual needs.

Before the step S5 of forming the second inorganic layer, after completing the depositing of the second metal layer 34 on the organic light emitting diode display device, a surface of a side of the second metal layer 34 facing away from the organic layer 33 is subjected to a plasma treatment.

Referring to FIG. 2 and FIG. 1, step S6 is to form a second inorganic layer, by depositing the second inorganic layer 35 on the second metal layer 34 by atomic layer deposition, wherein the second inorganic layer 35 completely covers the second metal layer 34. Specifically, the second metal layer 34 is first placed in a vacuum reaction chamber of an atomic layer deposition apparatus, treated with plasma to increase its surface activity; and the second inorganic layer 35 is formed on the second metal layer 34 by atomic layer deposition, wherein the second inorganic layer 35 completely covers the second metal layer 34, and the second inorganic layer 35 has a dielectric constant of 5-11, which includes the inorganic metal oxide film or the inorganic metal nitride film, and specifically includes Al₂O₃, ZrO, HfO, or SiN_{X}. The second inorganic layer 35 has a thickness ranging from 0.02 to 0.05 um. It can be seen that in the embodiment, the second inorganic layer 35 has the same composition as the first inorganic layer 31.

As shown in FIG. 6, the dielectric properties of the first inorganic layer 31 were tested by taking an aluminum oxide film as the first inorganic layer 31 as an example, that is, the dielectric properties of the aluminum oxide film obtained by the atomic layer deposition were tested. The obtained aluminum oxide film was detected to be 20 nm by an ellipsometer, and a current density change of the film was detected by gradually increasing the voltage value at opposite ends of the film. It was confirmed that its extreme voltage density was 8.7 MV/cm, having good dielectric properties.

The present invention has an advantageous effect of providing an organic light emitting diode display device and a method of fabricating the same, which makes the entire encapsulation layer thinner by providing a metal layer between the inorganic layer and the organic layer of the encapsulation layer, thereby enhancing the bonding strength between the organic layer and the inorganic layer, avoiding the defects of the inorganic layer and the metal layer when used alone, improving the stability thereof, ensuring good water-oxygen barrier property and bending resistance, and satisfying requirements of the flexible electronic packaging technology.

While the invention has been described by way of example and in terms of the preferred embodiments, it is to be understood that the invention is not limited to the disclosed embodiments. To the contrary, it is intended to cover various modifications and similar arrangements. Therefore, the scope of the appended claims should be accorded the broadest interpretation so as to encompass all such modifications and similar arrangements.

What is claimed is:

1. An organic light emitting diode (OLED) display device, comprising
an array substrate;
a light emitting layer disposed on the array substrate; and
an encapsulation layer disposed on a side of the light emitting layer facing away from the array substrate, wherein the encapsulation layer comprises:
a first inorganic layer;
a first metal layer disposed on the first inorganic layer;
an organic layer disposed on the first metal layer;
a second metal layer disposed on the organic layer; and
a second inorganic layer disposed on the second metal layer.

2. The OLED display device according to claim 1, wherein the first inorganic layer and the second inorganic layer are prepared by atomic layer deposition.

3. The OLED display device according to claim 1, wherein the first metal layer and the second metal layer are made of aluminum.

4. The OLED display device according to claim 1, wherein each of the first metal layer and the second metal layer has a thickness ranging from 50 to 150 nm.

5. The OLED display device according to claim 1, wherein the organic layer comprises doped particles, and the doped particles comprise desiccant particles and a coupling agent.

6. A method of fabricating the OLED display device according to claim 1, comprising the following steps:
forming an OLED, by forming a light emitting layer on an array substrate, such that the array substrate and the light emitting layer form the OLED;
forming a first inorganic layer, by depositing the first inorganic layer by atomic layer deposition on a surface of a side of the light emitting layer of the OLED facing away from the array substrate;
forming a first metal layer, by preparing the first metal layer on the first inorganic layer;
forming an organic layer, by preparing the organic layer on a surface of a side of the first metal layer facing away from the first inorganic layer;
forming a second metal layer, by preparing the second metal layer on the organic layer;
forming a second inorganic layer, by depositing the second inorganic layer on the second metal layer by atomic layer deposition, wherein the second inorganic layer completely covers the second metal layer.

7. The method of fabricating an OLED display device according to claim 6, wherein
before the step of forming the first metal layer, the method further comprises: after completing the depositing of the first inorganic layer on the OLED display device, plasma treating a surface of the first inorganic layer.

8. The method of fabricating an OLED display device according to claim 6, wherein
the step of forming the organic layer comprises: spin-coating an organic solution doped with desiccant particles and a coupling agent on the surface of the side of the first metal layer facing away from the inorganic layer.

9. The method of fabricating an OLED display device according to claim 6, wherein
before the step of forming the second inorganic layer, the method further comprises: after completing the depositing of the second metal layer on the OLED display device, plasma treating the surface of the side of the second metal layer facing away from the organic layer.

10. The method of fabricating an OLED display device according to claim 6, wherein the first metal layer and the second metal layer are prepared by atomic deposition, and each of the first metal layer and the second metal layer has a thickness ranging from 50 to 150 nm.
